(19) United States
(12) Patent Application Publication
(10) Pub. No.: US 2023/0275041 A1
(43) Pub. Date: Aug. 31, 2023

(54) IMAGE SENSOR

(71) Applicant: SAMSUNG ELECTRONICS CO., LTD., Suwon-si (KR)

(72) Inventors: Young Gu JIN, Osan-si (KR); Jung Chak AHN, Yongin-si (KR); Young Sun OH, Hwaseong-si (KR)

(21) Appl. No.: 17/973,702

(22) Filed: Oct. 26, 2022

(30) Foreign Application Priority Data
Feb. 25, 2022 (KR) 10-2022-0025417

(51) Int. Cl. H01L 23/60; H01L 27/146

(52) U.S. Cl. CPC H01L 23/60; H01L 27/14645; H01L 27/14627; H01L 27/1463; H01L 27/14636; H01L 27/1464; H01L 27/14683

(57) ABSTRACT

An image sensor includes a substrate having a first surface and a second surface opposing to the first surface, first pixel separation patterns defining a plurality of unit pixels, which include photoelectric conversion regions in the substrate, each of the first pixel separation patterns including a first conductive film and a second conductive film on the first conductive film, and microlenses on the second surface of the substrate, wherein the first conductive film extends along sidewalls of the second conductive film to separate the second conductive film from the substrate, the first conductive film has a greater reflectance than the second conductive film for a predetermined wavelength range, and the second conductive film has a greater step coverage than the first conductive film.

### CROSS-REFERENCE TO RELATED APPLICATION

This application claims priority from Korean Patent Application No. 10-2022-0025417, filed on Feb. 25, 2022, in the Korean Intellectual Property Office, and all the benefits accruing therefrom under 35 U.S.C. 119, the contents of which in its entirety are herein incorporated by reference.

### BACKGROUND

### 1. Field

The present disclosure relates to an image sensor.

### 2. Description of the Related Art

An image sensor is a type of semiconductor device that converts optical information into electrical signals. Examples of the image sensor include a charge-coupled device (CCD) image sensor and a complementary metal-oxide semiconductor (CMOS)-type image sensor. Image sensors may be configured in the form of a package, and the package may be configured to be able to protect the image sensors and allow light to be incident upon the light-receiving areas or sensing areas of the image sensors.

### SUMMARY

According to an aspect of the present disclosure, there is provided an image sensor including a substrate including a first surface and a second surface opposing to the first surface, first pixel separation patterns defining a plurality of unit pixels, which include photoelectric conversion regions in the substrate, each of the first pixel separation patterns including a first conductive film and a second conductive film on the first conductive film, and microlenses on the second surface of the substrate, wherein the first conductive film extends along sidewalls of the second conductive film to separate the second conductive film from the substrate, the first conductive film has a greater reflectance than the second conductive film for a predetermined wavelength range, and the second conductive film has a greater step coverage than the first conductive film.

According to another aspect of the present disclosure, there is provided an image sensor including a substrate including a first surface and a second opposing to the first surface, a plurality of unit pixels including photoelectric conversion regions in the substrate, first pixel separation patterns defining a plurality of unit pixels in the substrate and filling first pixel separation trenches, well regions and floating diffusion regions in the substrate; transistors on the first surface of the substrate; a wiring structure including an inter-wiring insulating layer, which covers the transistors, and a plurality of wires, which are in the inter-wiring insulating layer, and microlenses on the second surface of the substrate, wherein each of the first pixel separation patterns includes a first insulating film extending along sidewalls of each of the first pixel separation trenches, a first conductive film on the first insulating film, and a second conductive film filling each of the first pixel separation trenches, on the first conductive film, the first conductive film has a greater reflectance than the second conductive film for a predetermined wavelength range, and the second conductive film has a greater step coverage than the first conductive film.

According to still another aspect of the present disclosure, there is provided an image sensor including a substrate including a first surface and a second opposing to the first surface having first and second surfaces, which are opposite to each other, first pixel separation patterns extending from the first surface to the second surface of the substrate and filling first pixel separation trenches, a plurality of unit pixels including photoelectric conversion regions in the substrate, the unit pixels being defined by the first pixel separation patterns, and microlenses on the second surface of the substrate, wherein each of the first pixel separation patterns includes a first insulating film on sidewalls of each of the first pixel separation trenches, a first conductive film on the first insulating film, and a second conductive film filling each of the first pixel separation trenches, on the first conductive film, and the first conductive film has a greater reflectance than the second conductive film for a predetermined wavelength range.

### BRIEF DESCRIPTION OF THE DRAWINGS

Features will become apparent to those of skill in the art by describing in detail exemplary embodiments with reference to the attached drawings, in which:

FIG. 1 is a block diagram of an image sensing device according to some embodiments of the present disclosure;

FIG. 2 is a circuit diagram of a unit pixel of an image sensor according to some embodiments of the present disclosure;

FIG. 3 is a cross-sectional view of an image sensor according to some embodiments of the present disclosure;

FIG. 4 is a graph showing the reflectance of materials versus wavelength.

FIG. 5 is a cross-sectional view of an image sensor according to some embodiments of the present disclosure;

FIG. 6 is a cross-sectional view of an image sensor according to some embodiments of the present disclosure;

FIG. 7 is a cross-sectional view of an image sensor according to some embodiments of the present disclosure;

FIG. 8 is a cross-sectional view of an image sensor according to some embodiments of the present disclosure;

FIG. 9 is a cross-sectional view of an image sensor according to some embodiments of the present disclosure;

FIG. 10 is a cross-sectional view of an image sensor according to some embodiments of the present disclosure;

FIG. 11 is a cross-sectional view of an image sensor according to some embodiments of the present disclosure;

FIG. 12 is a cross-sectional view of an image sensor according to some embodiments of the present disclosure;

FIG. 13 is a cross-sectional view of an image sensor according to some embodiments of the present disclosure;

FIG. 14 is a cross-sectional view of an image sensor according to some embodiments of the present disclosure;

FIG. 15 is a cross-sectional view of an image sensor according to some embodiments of the present disclosure;

FIGS. 16 through 21 are cross-sectional views of stages in a method of fabricating an image sensor according to some embodiments of the present disclosure;

FIG. 22 is a layout view of an image sensor according to some embodiments of the present disclosure; and

FIG. 23 is a cross-sectional view of an image sensor according to some embodiments of the present disclosure.

### DETAILED DESCRIPTION

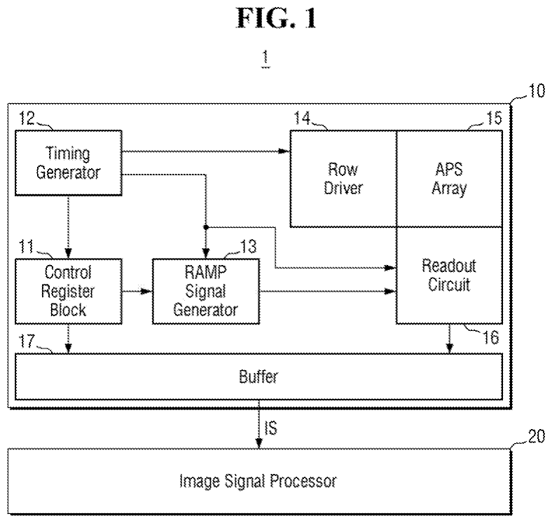

FIG. 1 is a block diagram of an image sensing device according to some embodiments of the present disclosure.

Referring to FIG. 1, an image sensing device 1 may include an image sensor 10 and an image signal processor 20.

The image sensor 10 may generate an image signal IS by sensing an image of a target object using light. In some embodiments, the image signal IS may be, e.g., a digital signal.

The image signal IS may be provided to and processed by the image signal processor 20. The image signal processor 20 may receive the image signal IS from a buffer 17 of the image sensor 10 and may process the image signal IS so that the image signal IS may be suitable to be displayed.

In some embodiments, the image signal processor 20 may perform digital binning on the image signal IS output from the image sensor 10. The image signal IS output from the image sensor 10 may be a raw image signal from an active pixel sensor (APS) array 15 that is yet to be subjected to analog binning or an image signal IS that has already been subjected to analog binning.

In some embodiments, the image sensor 10 and the image signal processor 20 may be separate. For example, the image sensor 10 may be mounted in a first chip, the image signal processor 20 may be mounted in a second chip, and the image sensor 10 and the image signal processor 20 may communicate with each other via a predetermined interface. In another example, the image sensor 10 and the image signal processor 20 may be incorporated into a single package, e.g., a multichip package (MCP).

The image sensor 10 may include the APS array 15, a control register block 11, a timing generator 12, a row driver 14, a readout circuit 16, a ramp signal generator 13, and the buffer 17.

The control register block 11 may control the operation of the image sensor 10. The control register block 11 may transmit operation signals directly to the timing generator 12, the ramp signal generator 13, and the buffer 17.

The timing generator 12 may generate an operation timing reference signal that can be referenced for the operation of various elements of the image sensor 10. The operation timing reference signal may be transmitted to the ramp signal generator 13, the row driver 14, and the readout circuit 16.

The ramp signal generator 13 may generate and transmit ramp signals for use in the readout circuit 16. For example, the readout circuit 16 may include a correlated double sampler (CDS) and a comparator, and the ramp signal generator 13 may generate and transmit ramp signals for use in the CDS and the comparator.

The row driver 14 may selectively activate each row of the APS array 15. The APS array 15 may sense an external image. The APS array 15 may include a plurality of pixels (or unit pixels).

The readout circuit 16 may sample a pixel signal provided from the APS array 15, may compare the pixel signal with a ramp signal and may convert an analog image signal (or data) into a digital image signal (or data) based on the result of the comparison.

The buffer 17 may include, e.g., a latch. The buffer 17 may temporarily store the image signal IS and may transmit the image signal IS to an external memory or an external device.

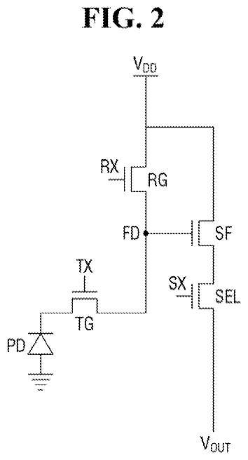

FIG. 2 is a circuit diagram of a unit pixel of an image sensor according to some embodiments of the present disclosure.

Referring to FIG. 2, a unit pixel may include a photoelectric converter PD, a transfer transistor TG, a floating diffusion region FD, a reset transistor RG, a source follower transistor SF, and a selection transistor SEL.

The photoelectric converter PD may generate electric charge in proportion to the amount of light incident thereupon from the outside. The photoelectric converter PD may be coupled to the transfer transistor TG, which transmits the generated electric charge to the floating diffusion region FD. As the floating diffusion region FD, which is a region that converts electric charge into a voltage, has parasitic capacitance, electric charge can be accumulatively stored in the floating diffusion region FD.

One end of the transfer transistor TG may be connected to the photoelectric converter PD, and the other end of the transfer transistor TG may be connected to the floating diffusion region FD. The transfer transistor TG may be formed as a transistor driven by a predetermined bias (e.g., a transmission signal TX). That is, the transfer transistor TG may transmit the electric charge generated by the photoelectric converter PD to the floating diffusion region FD in accordance with the transmission signal TX.

The source follower transistor SF may amplify the electric potential of the floating diffusion region FD, which receives the electric charge from the photoelectric converter PD, and may output the amplified electric potential to an output line VOUT. When the source follower transistor SF is turned on, a predetermined electric potential provided to the drain of the source follower transistor SF, e.g., a power supply voltage V_{DD}, may be transmitted to the drain of the selection transistor SEL.

The selection transistor SEL may select a row of unit pixels to be read. The selection transistor SEL may be formed as a transistor driven by a selection line (e.g., a row selection signal SX) applying a predetermined bias.

The reset transistor RG may periodically reset the floating diffusion region FD. The reset transistor RG may be formed as a transistor driven by a reset line applying a predetermined bias (e.g., a reset signal RX). When the reset transistor RG is turned on by the reset signal RX, a predetermined electric potential provided to the drain of the reset transistor RG, e.g., the power supply voltage V_{DD}, may be transmitted to the floating diffusion region FD.

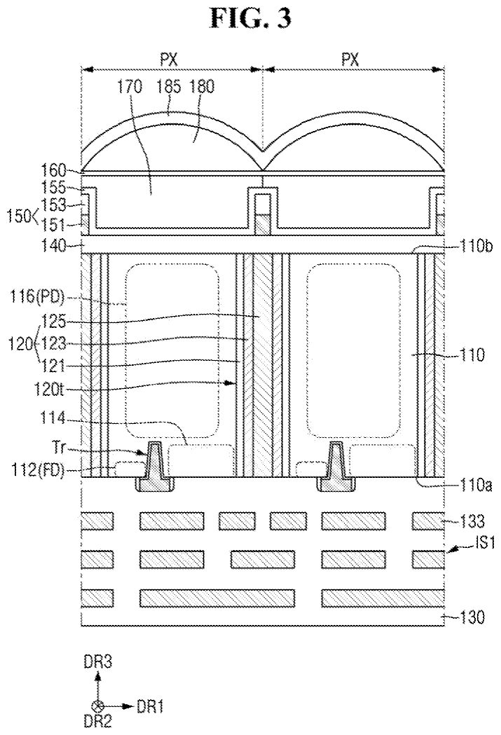

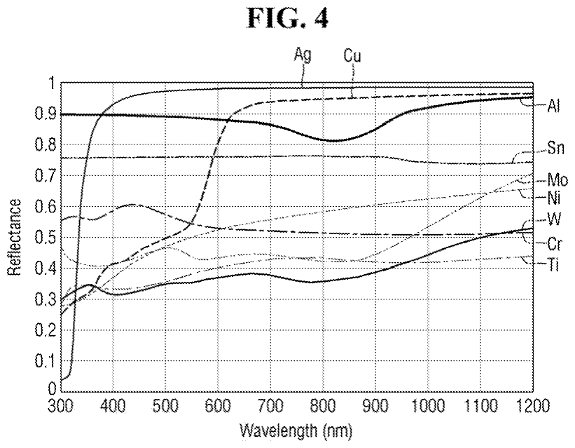

FIG. 3 is a cross-sectional view of an image sensor according to some embodiments of the present disclosure. FIG. 4 is a graph showing the reflectance of materials versus wavelength.

Referring to FIG. 3, the image sensor may include a first substrate 110, photoelectric conversion regions 116, a wiring structure IS1, first pixel separation patterns 120, a first planarization layer 140, grid patterns 150, a first passivation film 155, a second planarization layer 160, color filters 170, microlenses 180, and a second passivation film 185.

The first substrate 110 may have first and second surfaces 110a and 110b, which are opposite to each other. The first surface 110a may also be referred to as a front side, e.g., a surface facing the wiring structure IS1, and the second surface 110b may also be referred to as a back side, e.g., a surface facing the color filters 170. In some embodiments, the second surface 110b of the first substrate 110 may be a light-receiving surface. That is, the image sensor may be a back side-illuminated (BSI) image sensor.

The first substrate 110 may be a semiconductor substrate. For example, the first substrate 110 may be a bulk silicon substrate or a silicon-on-insulator (SOI) substrate. The first substrate 110 may be a silicon substrate or may include a material other than silicon, e.g., silicon germanium, indium antimonide, a lead tellurium compound, indium arsenic, indium phosphide, gallium arsenide, and/or gallium antimonide. Alternatively, the first substrate 110 may be a base substrate having an epitaxial layer formed thereon.

In some embodiments, the first substrate 110 may have a first conductivity type. For example, the first substrate 110 may include p-type impurities, e.g., boron (B). The first conductivity type will hereinafter be described as referring to a p-type, but the present disclosure is not limited thereto, e.g., the first conductivity type may be an n-type.

A plurality of unit pixels PX may be formed on the first substrate 110. For example, the unit pixels PX may be arranged two-dimensionally, e.g., in the form of a matrix in the first and second directions DR1 and DR2.

The unit pixels PX may include the photoelectric conversion regions 116. The photoelectric conversion regions 116 may be formed in the first substrate 110. The photoelectric conversion regions 116 may generate electric charge in proportion to the amount of light incident thereupon from the outside.

The photoelectric conversion regions 116 may be formed in the first substrate 110, in the unit pixels PX, e.g., each unit pixel PX may include one photoelectric conversion region 116. The photoelectric conversion regions 116 may correspond to the photoelectric converter PD of FIG. 2. The photoelectric conversion regions 116 may generate electric charge in proportion to the amount of light incident thereupon from the outside.

The photoelectric conversion regions 116 may have a second conductivity type, which is different from the first conductivity type. The second conductivity type will hereinafter be described as referring to the n-type. Alternatively, the second conductivity type may be the p-type. The photoelectric conversion regions 116 may be formed by implanting ions of n-type impurities (e.g., phosphorus (P) or arsenic (As)) into the first substrate 110, which is of the p-type.

In some embodiments, the photoelectric conversion regions 116 may have a potential gradient in a direction (e.g., a vertical direction) intersecting the first and second surfaces 110a and 110b of the first substrate 110. For example, the impurity concentration in the photoelectric conversion regions 116 may gradually decrease from the first surface 110a to the second surface 110b.

Impurity regions 112 may be formed in the first substrate 110. The impurity regions 112 may have the second conductivity type. For example, the impurity regions 112 may be formed by implanting ions of n-type impurities into the first substrate 110, which is of the p-type. The impurity regions 112 may correspond to the floating diffusion regions FD of FIG. 2.

In some embodiments, the impurity regions 112 may have a higher impurity concentration than the photoelectric conversion regions 116 and may have the second conductivity type. For example, the impurity regions 112 may be formed by implanting a high concentration of ions of n-type impurities (i.e., n+ impurities) into the first substrate 110, which is of the p-type.

In some embodiments, well regions 114 may be further formed in the unit pixels PX. The well regions 114 may be formed in the first substrate 110, on the photoelectric conversion regions 116. The well regions 114 may be adjacent to the first surface 110a of the first substrate 110. For example, the well regions 114 may extend from the first surface 110a of the first substrate 110. In some embodiments, the well regions 114 may be formed deeper than the impurity regions 112, e.g., a thickness of the well regions 114 may be greater than that of the impurity regions 112 I the vertical direction (e.g., along the DR3 direction).

The well regions 114 may have the first conductivity type. In some embodiments, the well regions 114 may have a higher impurity concentration than the first substrate 110 and may have the first conductivity type. For example, the well regions 114 may be formed by implanting a high concentration of ions of p-type impurities (i.e., p+ impurities) into the first substrate 110, which is of the p-type.

Transistors Tr may be formed on the first surface 110a of the first substrate 110, e.g., the transistors Tr may penetrate through the first surface 110a of the first substrate 110. The transistors Tr may be connected to the photoelectric conversion regions 116 and may thus form various transistors for processing electrical signals. For example, the transistors Tr may form various transistors, e.g., the transfer transistor TG, the reset transistor RG, the source follower transistor SF, and the selection transistor SEL of FIG. 2. In some embodiments, the transistors Tr may be transfer transistors TG formed on the first substrate 110, between the photoelectric conversion regions 116 and the impurity regions 112.

In some embodiments, the gates of the transistors Tr may be vertical transfer gates. That is, at least parts of the gates of the transistors Tr may be buried in the first substrate 110. For example, trenches, which extend from the first surface 110a of the first substrate 110 toward the second surface 110b of the first substrate 110, may be formed in the first substrate 110. At least parts of the gates of the transistors Tr may be formed to fill the trenches. Accordingly, the bottom surfaces of the gates of the transistors Tr may be formed on an upper side, in the third direction DR3, of the first surface 110a of the first substrate 110, e.g., the bottom surfaces of the gates of the transistors Tr may be formed within the first substrate 110 at a predetermined distance from the first surface 110a in the third direction DR3. In some embodiments, the width of the gates of the transistors Tr may gradually decrease in a direction oriented from the first surface 110a toward the second surface 110b of the first substrate 110 because of the characteristics of an etching process for forming the trenches.

The first wiring structure IS1 may be formed on the first substrate 110. For example, the first wiring structure IS1 may be formed, e.g., directly, on the first surface 110a of the first substrate 110. Also, the first wiring structure IS1 may cover, e.g., the first surface 110a of the first substrate 110.

The first wiring structure IS1 may include one or more wires. For example, the first wiring structure IS1 may include a first wiring insulating film 130 and a plurality of first wires 133. Any suitable layout and number of layers of wiring in the first wiring structure IS1 may be used.

The first wires 133 may be electrically connected to the unit pixels PX. For example, the first wires 133 may be connected to the transistors Tr. The first wiring insulating film 130 may include at least one of, e.g., silicon oxide, silicon nitride, silicon oxynitride, and a low-k material having a lower dielectric constant than silicon oxide.

The first pixel separation patterns 120 may be formed to surround the unit pixels PX in a plan view. The first pixel separation patterns 120 may define the unit pixels PX. The first pixel separation patterns 120 may be formed in the first substrate 110 in the form of a lattice, in a plan view, to separate the unit pixels PX from one another.

The first pixel separation patterns 120 may be formed in the first substrate 110. For example, the first pixel separation patterns 120 may be buried in first pixel separation trenches 120t, which are formed deep by patterning the first substrate 110.

In some embodiments, the first pixel separation patterns 120 may penetrate the first substrate 110. For example, the first pixel separation patterns 120 may extend from the first surface 110a to the second surface 110b.

In some embodiments, the width of the first pixel separation patterns 120 may be uniform in a direction oriented away from the first surface 110a of the first substrate 110. The term “uniform,” as used herein, not only means being completely identical, but also encompasses being almost identical with a slight difference that may be caused by process margins or the like.

Alternatively, in some embodiments, the width of the first pixel separation patterns 120 may gradually decrease in a direction oriented away from the first surface 110a of the first substrate 110 because of the characteristics of an etching process for forming the first pixel separation patterns 120. For example, the etching process for forming the first pixel separation patterns 120 may be performed on the first surface 110a of the first substrate 110.

In some embodiments, each of the first pixel separation patterns 120 may include first insulating films 121, first conductive films 123, and a second conductive film 125.

In some embodiments, the first insulating films 121 may extend, e.g., directly, along the sidewalls of a first pixel separation trench 120t. The first conductive films 123 may extend, e.g., directly, along the first insulating films 121, e.g., so the first insulating film 121 may be between the sidewall of the first pixel separation trench 120t and the first conductive film 123. The second conductive film 125 may be disposed, e.g., directly, on the first conductive films 123 to fill the first pixel separation trench 120t, e.g., so the second conductive film 125 may be between two first conductive films 123. In other words, the first conductive films 123 may be, e.g., continuously, disposed on the, e.g., entire, sidewalls of the second conductive film 125 to, e.g., completely, separate the first substrate 110 and the second conductive film 125. The first insulating films 121 may be disposed on the first conductive films 123 to, e.g., completely, separate the first conductive films 123 and the first substrate 110. For example, the first and second conductive films 123 and 125 may be formed of different materials.

In some embodiments, the reflectance of the first conductive films 123 for a particular wavelength range may be greater than the reflectance of the second conductive film 125 for the, e.g., same, particular wavelength range. The first conductive film 123 may have a reflectance of 0.7 or greater for a visible or infrared (IR) wavelength range, e.g., a fraction of the electromagnetic power reflected from the first conductive film 123 may be greater than 0.7 and smaller than 1. Accordingly, an image sensor capable of improving or preventing crosstalk can be provided.

In some embodiments, the step coverage of the second conductive film 125 may be greater than the step coverage of the first conductive films 123. The second conductive film 125 may have a step coverage of 0.8 or greater. The term “step coverage,” as used herein, may refer to bottom- or side-step coverage, e.g., so a thickness of a deposited film on the bottom or sidewalls of the trench may be between 0.8 and 1.0 of a thickness of the deposited film on the top.

During the deposition of the second conductive film 125, the first pixel separation trenches 120t may be filled with the first pixel separation patterns 120. As a result, voltages can be stably applied to the first pixel separation patterns 120, and an image sensor with improved dark current characteristics can be provided.

The first insulating films 121 may include, e.g., oxide films having a lower refractive index than the first substrate 110. For example, the first insulating films 121 may include at least one of silicon oxide, aluminum oxide, silicon nitride, hafnium oxide, tantalum oxide, and a combination thereof.

The first conductive films 123 may include at least one of, e.g., aluminum (Al), silver (Ag), copper (Cu), and a combination thereof. Referring to FIG. 4, the first conductive films 123 may include Al for the visible wavelength range and Cu for an IR wavelength range. The second conductive films 125 may include at least one of, e.g., tungsten (W), polysilicon, silicide, and a combination thereof.

The first planarization layer 140 may be formed, e.g., directly, on the second surface 110b of the first substrate 110. The first planarization layer 140 may cover the second surface 110b of the first substrate 110.

The first planarization layer 140 may include an insulating material. For example, the first planarization layer 140 may include at least one of silicon oxide, silicon nitride, silicon oxynitride, aluminum oxide, hafnium oxide, and a combination thereof, but the present disclosure is not limited thereto.

In some embodiments, the first planarization layer 140 may be formed as a multilayer film. For example, the first planarization layer 140 may include an aluminum oxide film, a hafnium oxide film, a silicon oxide film, a silicon nitride film, and a hafnium oxide film that are sequentially stacked on the second surface 110b of the first substrate 110.

The first planarization layer 140 may function as an anti-reflection film and may improve the light reception of the photoelectric conversion regions 116 by preventing the reflection of light incident upon the first substrate 110. Also, the first planarization layer 140 may function as a typical planarization film and may thus allow the color filters 170 and the microlenses 180 to be formed to a uniform height.

The color filters 170 may be formed on the first planarization layer 140. The color filters 170 may be arranged to correspond to the unit pixels PX, e.g., in a one-to-one correspondence. For example, the color filters 170 may be arranged two-dimensionally (e.g., in the form of a matrix) in a plan view in the first and second directions DR1 and DR2.

The color filters 170 may be of various colors. For example, the color filters 170 may include red filters, green filters, and blue filters and may be arranged in a Bayer filter pattern. In another example, the color filters 170 may include yellow filters, magenta filters, and cyan filters and may further include white filters.

In some embodiments, the grid patterns 150 may be formed between the color filters 170. The grid patterns 150 may be formed on the first planarization layer 140. The grid patterns 150 may be formed in a grid shape in a plan view and may be interposed between the color filters 170.

In some embodiments, the grid patterns 150 may include conductive patterns 151 and low refractive index patterns 153. The conductive patterns 151 and the low refractive index patterns 153 may be sequentially stacked on, e.g., the first planarization layer 140.

The conductive patterns 151 may include a conductive material. For example, the conductive patterns 151 may include at least one of titanium (Ti), titanium nitride (TiN), tantalum (Ta), tantalum nitride (TaN), W, Al, Cu, and a combination thereof. The conductive patterns 151 may effectively prevent electrostatic discharge (ESD) defects by preventing electric charge generated by ESD from being accumulated on the surface (e.g., the first surface 110a) of the first substrate 110.

The low refractive index patterns 153 may include a material having a lower refractive index than silicon (Si). For example, the low refractive index patterns 153 may include at least one of silicon oxide, aluminum oxide, tantalum oxide, and a combination thereof. The low refractive index patterns 153 may improve the quality of an image sensor by refracting or reflecting light incident thereupon diagonally to improve the efficiency of collecting light.

In some embodiments, the first passivation film 155 may be formed on the first planarization layer 140 and the grid patterns 150. For example, the first passivation film 155 may conformally extend along the profile of the top surface of the first planarization layer 140 and the sides and the top surface of each of the grid patterns 150.

The first passivation film 155 may include, e.g., aluminum oxide. The first passivation film 155 may prevent the first planarization layer 140 and the grid patterns 150 from being damaged.

The second planarization layer 160 may be formed on the color filters 170. The second planarization layer 160 may cover the color filters 170. The second planarization layer 160 may include an insulating material, e.g., silicon oxide.

The microlenses 180 may be formed on the second planarization layer 160. The microlenses 180 may be arranged to correspond to the unit pixels PX, e.g., in a one-to-one correspondence. For example, the microlenses 180 may be arranged two-dimensionally (e.g., in the form of a matrix) on the plane including the first and second directions DR1 and DR2.

The microlenses 180 may have a convex shape with a predetermined radius of curvature. Accordingly, the microlenses 180 can condense light incident upon the photoelectric conversion regions 116. The microlenses 180 include, e.g., a light-transmitting resin.

In some embodiments, the second passivation film 185 may be formed on the microlenses 180. The second passivation film 185 may extend along the surfaces of the microlenses 180. The second passivation film 185 may include, e.g., an inorganic oxide film. For example, the second passivation film 185 may include at least one of silicon oxide, titanium oxide, zirconium oxide, hafnium oxide, and a combination thereof. In some embodiments, the second passivation film 185 may include a low-temperature oxide (LTO).

The second passivation film 185 may protect the microlenses 180 from the outside. For example, the second passivation film 185 may include an inorganic oxide film and may thus protect the microlenses 180, which include an organic material. Also, the second passivation film 185 may improve the quality of an image sensor by improving the light collection efficiency of the microlenses 180. For example, the second passivation film 185 may fill empty spaces between the microlenses 180 and may thus reduce the reflection, refraction, and diffusion of incident light arriving in the empty spaces between the microlenses 180.

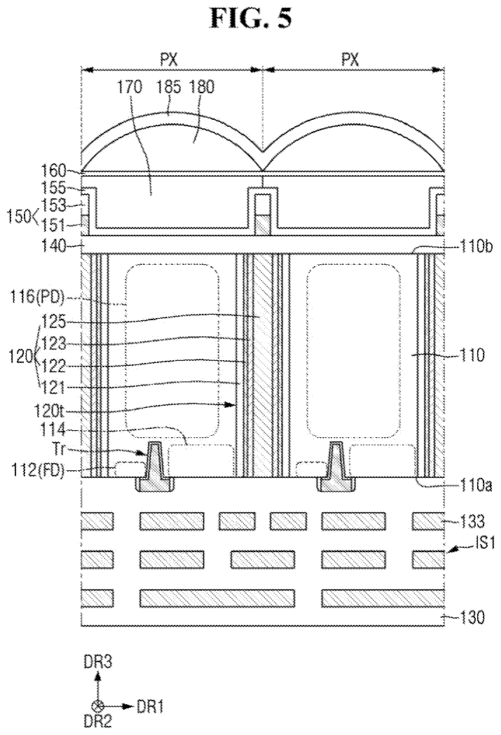

FIG. 5 is a cross-sectional view of an image sensor according to some embodiments of the present disclosure. For convenience, the image sensor of FIG. 5 will hereinafter be described, focusing mainly on the differences relative to the image sensor of FIG. 3.

Referring to FIG. 5, each of the first pixel separation patterns 120 may further include first barrier films 122. The first barrier films 122 may be disposed between the first insulating films 121 and the first conductive films 123. The first barrier films 122 may extend along sidewalls of the first conductive films 123. The first barrier films 122 may be disposed on the sidewalls of the first conductive films 123 to, e.g., completely, separate the first insulating films 121 and the first conductive films 123.

The first barrier films 122 may prevent or suppress the diffusion of a metallic component from the first conductive films 123 into the first insulating films 121. The first barrier films 122 may include at least one of, e.g., Ti, TiN, silicon carbonitride, cobalt (Co), silicide, and a combination thereof. Also, the first barrier films 122 may be formed as multilayer films.

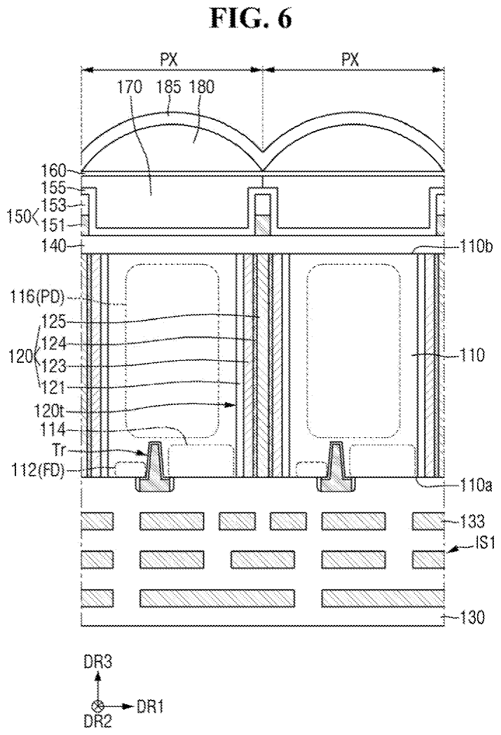

FIG. 6 is a cross-sectional view of an image sensor according to some embodiments of the present disclosure. For convenience, the image sensor of FIG. 6 will hereinafter be described, focusing mainly on the differences relative to the image sensor of FIG. 3.

Referring to FIG. 6, each of the first pixel separation patterns 120 may further include third conductive films 124. The third conductive films 124 may be disposed between the first conductive films 123 and the second conductive film 125. The third conductive films 124 may extend along the sidewalls of the second conductive film 125. The third conductive films 124 may be disposed on the second conductive film 125 to, e.g., completely, separate the first conductive films 123 and the second conductive film 125.

The third conductive films 124 may improve or reduce the contact resistance between the first conductive films 123 and the second conductive film 125. The third conductive films 124 may include at least one of, e.g., silicide and an alloy containing silicide.

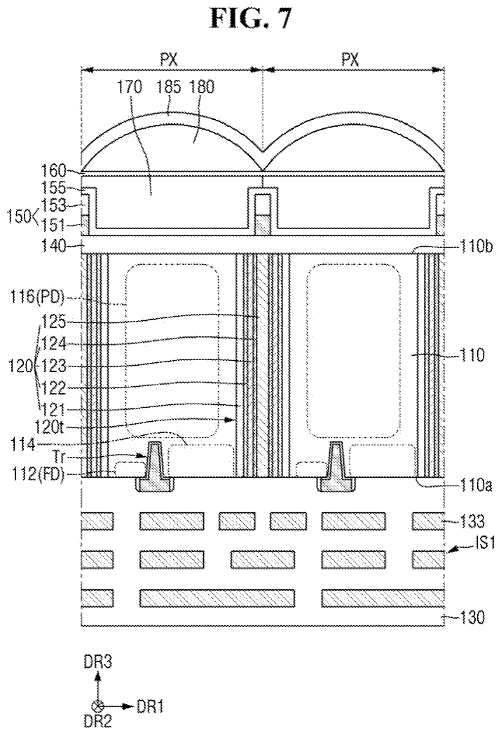

FIG. 7 is a cross-sectional view of an image sensor according to some embodiments of the present disclosure. For convenience, the image sensor of FIG. 7 will hereinafter be described, focusing mainly on the differences relative to the image sensor of FIG. 3.

Referring to FIG. 7, each of the first pixel separation patterns 120 may further include the first barrier films 122 and the third conductive films 124. The first barrier films 122 may correspond to the first barrier films 122 of FIG. 5, and the third conductive films 124 may correspond to the third conductive films 124 of FIG. 6.

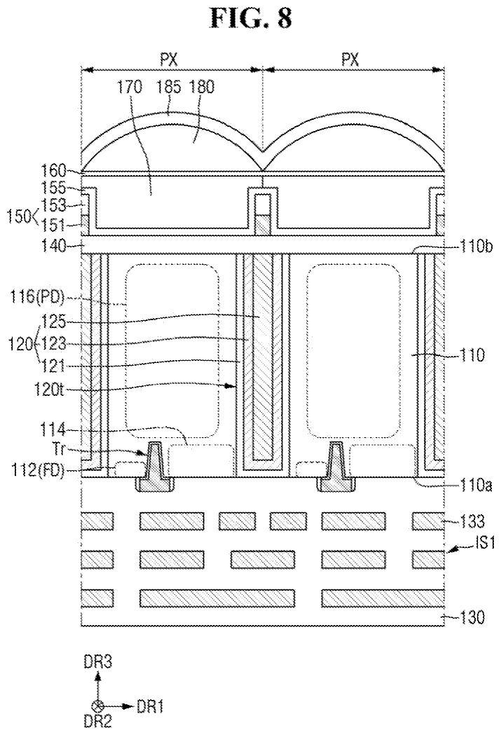

FIG. 8 is a cross-sectional view of an image sensor according to some embodiments of the present disclosure. For convenience, the image sensor of FIG. 8 will hereinafter be described, focusing mainly on the differences relative to the image sensor of FIG. 3.

Referring to FIG. 8, in each of the first pixel separation patterns 120, the first insulating film 121 may extend along the sidewalls and bottom surface of the first pixel separation trench 120t. The first conductive film 123 may extend, e.g., continuously, along the, e.g., entire, first insulating film 121. The second conductive film 125 may be disposed on the first conductive film 123 to fill the first pixel separation trench 120t. The first conductive film 123 may extend along the sidewalls and the bottom surface of the second conductive film 125.

In some embodiments, the first pixel separation patterns 120 may penetrate the first substrate 110. For example, the first pixel separation patterns 120 may extend from the second surface 110b to the first surface 110a of the first substrate 110, e.g., the first pixel separation patterns 120 may extend from the second surface 110b to the first surface 110a of the first substrate 110 along an entire thickness of the first substrate 110 in the third direction DR3.

In some embodiments, the width of the first pixel separation patterns 120 may be uniform in a direction oriented away from the second surface 110b of the first substrate 110. Alternatively, in some embodiments, the width of the first pixel separation patterns 120 may gradually decrease in a direction oriented away from the second surface 110b of the first substrate 110 due to the characteristics of an etching process for forming the first pixel separation patterns 120. For example, the etching process for forming the first pixel separation patterns 120 may be performed on the second surface 110b of the first substrate 110. As described above with FIGS. 5 through 7, each of the first pixel separation patterns 120 may further include at least one of the first barrier film 122 and the third conductive film 124.

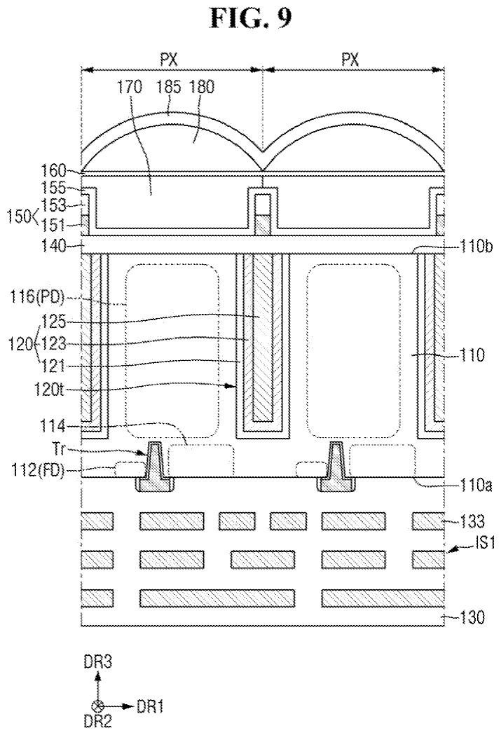

FIG. 9 is a cross-sectional view of an image sensor according to some embodiments of the present disclosure. For convenience, the image sensor of FIG. 9 will hereinafter be described, focusing mainly on the differences relative to the image sensor of FIG. 3.

Referring to FIG. 9, the first pixel separation patterns 120 may penetrate only part of the first substrate 110. For example, the first pixel separation patterns 120 may only partially penetrate the first substrate 110 from the second surface 110b of the first substrate 110, e.g., the first pixel separation patterns 120 may extend from the second surface 110b into the first substrate 110 without reaching the first surface 110a. The bottom surfaces of the first pixel separation patterns 120 may be disposed in the first substrate 110, e.g., a predetermined distance from the first surface 110a. The bottom surfaces of the first pixel separation patterns 120 may be defined based on the third direction DR3, which is a direction from the first surface 110a to the second surface 110b of the first substrate 110.

For example, as described above with FIGS. 5 through 7, The first pixel separation patterns 120 may further include at least one of the first barrier film 122 and the third conductive film 124.

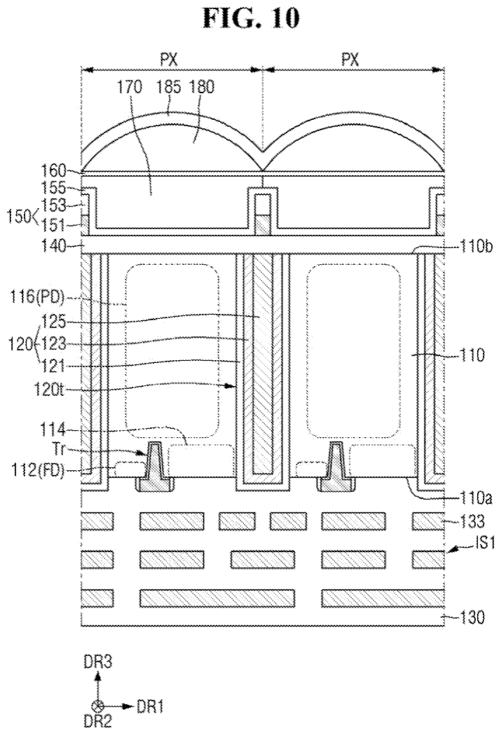

FIG. 10 is a cross-sectional view of an image sensor according to some embodiments of the present disclosure. For convenience, the image sensor of FIG. 10 will hereinafter be described, focusing mainly on the differences relative to the image sensor of FIG. 3.

Referring to FIG. 10, the first pixel separation patterns 120 may protrude from the first surface 110a of the first substrate 110. The first pixel separation patterns 120 may penetrate the entire first substrate 110 and part of the wiring structure IS1. For example, the bottom surfaces of the first pixel separation patterns 120 may be disposed in the wiring structure IS1. The bottom surfaces of the first pixel separation patterns 120 may be disposed below the first surface 110a of the first substrate 110, e.g., the thickness of the first pixel separation patterns 120 may be larger than the thickness of the first substrate 110 in the third direction DR3.

For example, as described above with FIGS. 5 through 7, each of the first pixel separation patterns 120 may further include at least one of the first barrier film 122 and the third conductive film 124.

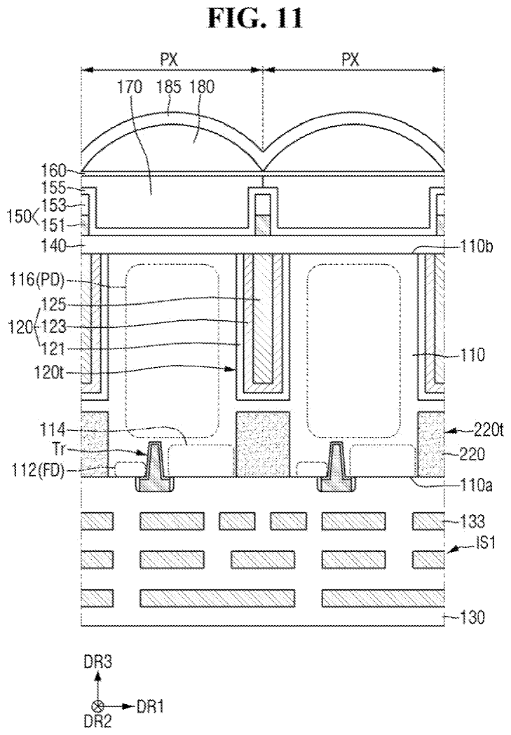

FIG. 11 is a cross-sectional view of an image sensor according to some embodiments of the present disclosure. For convenience, the image sensor of FIG. 11 will hereinafter be described, focusing mainly on the differences relative to the image sensor of FIG. 3.

Referring to FIG. 11, the image sensor may further include second pixel separation patterns 220. The second pixel separation patterns 220 may be formed to surround unit pixels PX in a plan view. The second pixel separation patterns 220 may define the unit pixels PX. The second pixel separation patterns 220 may be formed in the first substrate 110 in the form of a lattice, in a plan view, to separate the unit pixels PX from one another. The second pixel separation patterns 220 may be formed in the first substrate 110. For example, the second pixel separation patterns 220 may be buried in second pixel separation trenches 220t, which are formed by patterning the first substrate 110.

The second pixel separation patterns 220 may penetrate part of the first substrate 110. For example, the second pixel separation patterns 220 may penetrate part of the first substrate 110 from the first surface 110a of the first substrate 110. The top surfaces of the second pixel separation patterns 220 may be disposed in the first substrate 110. The top surfaces of the second pixel separation patterns 220 may be defined based on the third direction DR3, which is a direction from the first surface 110a to the second surface 110b of the first substrate 110.

In some embodiments, the width of the second pixel separation patterns 220 may be uniform in a direction oriented away from the first surface 110a of the first substrate 110. Alternatively, in some embodiments, the width of the second pixel separation patterns 220 may gradually decrease in a direction oriented away from the first surface 110a of the first substrate 110 due to the characteristics of an etching process for forming the second pixel separation patterns 220. For example, the etching process for forming the second pixel separation patterns 220 may be performed on the first surface 110a of the first substrate 110.

In some embodiments, the first pixel separation patterns 120 may be spaced apart from the second pixel separation patterns 220 in, e.g., within, the first substrate 110. The first pixel separation patterns 120 may overlap with at least parts of the second pixel separation patterns 220 in a direction oriented from the second surface 110b to the first surface 110a of the first substrate 110, e.g., the first and second pixel separation patterns 120 and 220 may be vertically aligned.

The second pixel separation patterns 220 may include, e.g., an insulating material. The second pixel separation patterns 220 may include at least one of, e.g., silicon oxide, aluminum oxide, tantalum oxide, and a combination thereof. In some embodiments, the second pixel separation patterns 220 may include a material having a lower refractive index than the first substrate 110.

For example, as described above with FIGS. 5 through 7, each of the first pixel separation patterns 120 may further include at least one of the first barrier film 122 and the third conductive film 124.

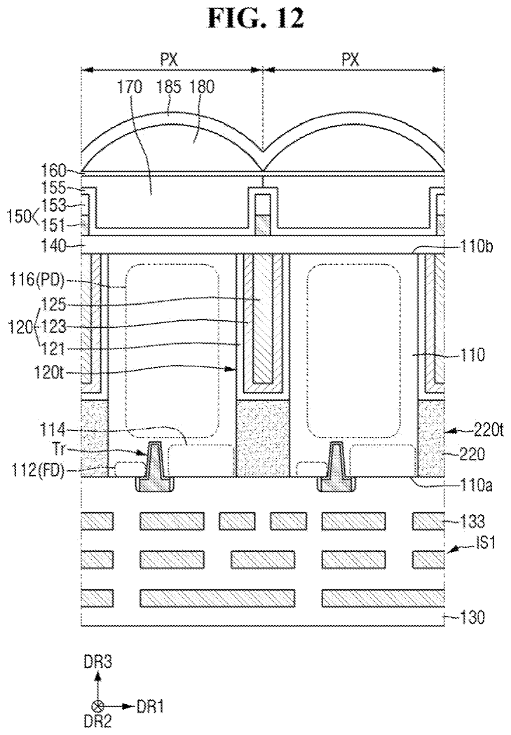

FIG. 12 is a cross-sectional view of an image sensor according to some embodiments of the present disclosure. For convenience, the image sensor of FIG. 12 will hereinafter be described, focusing mainly on the differences relative to the image sensor of FIG. 11.

Referring to FIG. 12, at least parts of the first pixel separation patterns 120 may be in contact with the second pixel separation patterns 220 in, e.g., within, the first substrate 110.

In some embodiments, the width of the bottom surfaces of the first pixel separation patterns 120 may be the same as the width of the top surfaces of the second pixel separation patterns 220. Alternatively, the width of the bottom surfaces of the first pixel separation patterns 120 may be different from the width of the top surfaces of the second pixel separation patterns 220. The bottom surfaces of the first pixel separation patterns 120 and the top surfaces of the second pixel separation patterns 220 may be defined based on the third direction DR3, which is a direction from the first surface 110a to for the second surface 110b of the first substrate 110.

For example, as described above with FIGS. 5 through 7, each of the first pixel separation patterns 120 may further include at least one of the first barrier film 122 and the third conductive film 124.

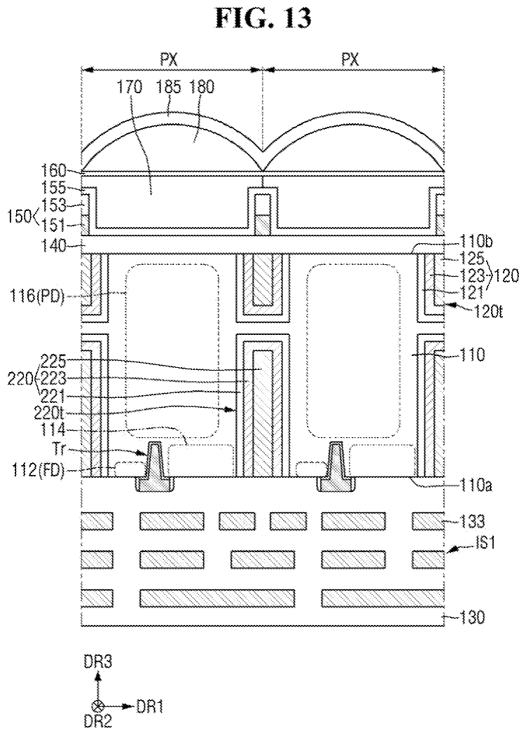

FIG. 13 is a cross-sectional view of an image sensor according to some embodiments of the present disclosure. For convenience, the image sensor of FIG. 13 will hereinafter be described, focusing mainly on the differences relative to the image sensor of FIG. 11.

Referring to FIG. 13, each of the second pixel separation patterns 220 may include a second insulating film 221, a fourth conductive film 223, and a fifth conductive film 225. For example, the second pixel separation patterns 220 may have a same or similar layered structure as the first pixel separation patterns 120.

In detail, the second insulating film 221 may extend along the sidewalls of the second pixel separation trench 220t. The fourth conductive film 223 may extend along the second insulating film 221. The fifth conductive film 225 may be disposed on the fourth conductive film 223 to fill the second pixel separation trench 220t. In other words, the fourth conductive film 223 may be disposed on the sidewalls of the fifth conductive film 225 to separate the fifth conductive film 225 from the first substrate 110. The second insulating film 221 may be disposed on the sidewalls of the fourth conductive film 223 to separate the fourth conductive film 223 from the first substrate 110.

In some embodiments, the reflectance of the fourth conductive film 223 for a particular wavelength range may be greater than the reflectance of the fifth conductive film 225 for the same particular wavelength range. The fourth conductive film 223 may have a reflectance of 70% or greater for the visible or IR wavelength range. Accordingly, an image sensor capable of improving or preventing crosstalk can be provided.

In some embodiments, the step coverage of the fifth conductive film 225 may be greater than the step coverage of the fourth conductive film 223. The fifth conductive film 225 may have a step coverage of 80% or greater.

The second insulating film 221 may include, e.g., an oxide film having a lower refractive index than the first substrate 110. For example, the second insulating film 221 may include at least one of silicon oxide, aluminum oxide, silicon nitride, hafnium oxide, tantalum oxide, and a combination thereof.

The fourth conductive film 223 may include at least one of, e.g., Al, Ag, Cu, and a combination thereof. For example, referring to FIG. 4, the fourth conductive film 223 may include Al for the visible wavelength range and may include Cu for the IR wavelength range. The fifth conductive film 225 may include at least one of, e.g., W, polysilicon, silicide, and a combination thereof.

For example, each of first pixel separation patterns 120 may include a different number of layers from each of the second pixel separation patterns 220. As described above with FIGS. 5 through 7, each of the first pixel separation patterns 120 may further include at least one of the first barrier film 122 and the third conductive film 124.

Each of the second pixel separation patterns 220 may further include at least one of a second barrier film between the second insulating film 221 and the fourth conductive film 223 and a sixth conductive film between the fourth and fifth conductive films 223 and 225. The second barrier film may include at least one of, e.g., Ti, TiN, silicon carbonitride, Co, silicide, and a combination thereof. The second barrier film may be formed as a multilayer film. The sixth conductive film may include at least one of, e.g., silicide and an alloy containing silicide.

For example, the first pixel separation patterns 120 may be vertically spaced apart from the second pixel separation patterns 220. In another example, the first pixel separation patterns 120 may be in contact with at least parts of the second pixel separation patterns 220.

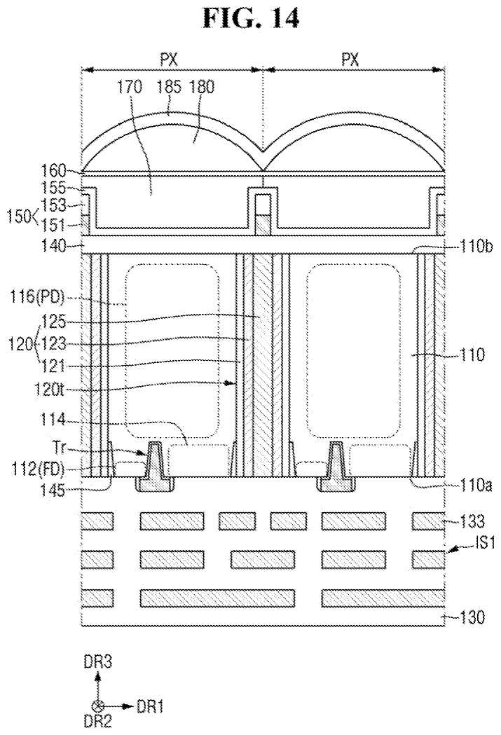

FIG. 14 is a cross-sectional view of an image sensor according to some embodiments of the present disclosure. For convenience, the image sensor of FIG. 14 will hereinafter be described, focusing mainly on the differences relative to the image sensor of FIG. 3.

Referring to FIG. 14, the image sensor may further include device isolation patterns 145. The device isolation patterns 145 may be disposed in the first substrate 110. For example, the device isolation patterns 145 may be disposed in trenches, which are formed in the first substrate 110 as recesses. The trenches may be recessed from the first surface 110a of the first substrate 110. The device isolation patterns 145 may be shallow trench isolation (STI) films. The device isolation patterns 145 may define active regions.

In some embodiments, the width of the device isolation patterns 145 may gradually decrease in a direction oriented away from the first surface 110a of the first substrate 110 due to the characteristics of an etching process for forming the device isolation patterns 145. For example, the etching process for forming the device isolation patterns 145 may be performed on the first surface 110a of the first substrate 110. Alternatively, in some embodiments, the width of the device isolation patterns 145 may be uniform in a direction oriented away from the first surface 110a of the first substrate 110.

The first pixel separation patterns 120 may overlap with the device isolation patterns 145, e.g., in a horizontal direction (e.g., the first DR1). Parts of the first pixel separation patterns 120 may be formed in the device isolation patterns 145. The first pixel separation patterns 120 may penetrate the device isolation patterns 145.

The device isolation patterns 145 may include an insulating material. The device isolation patterns 145 may include at least one of, e.g., silicon nitride, silicon oxide, and silicon oxynitride.

For example, as described above with FIGS. 5 through 7, each of the first pixel separation patterns 120 may further include at least one of the first barrier film 122 and the third conductive film 124.

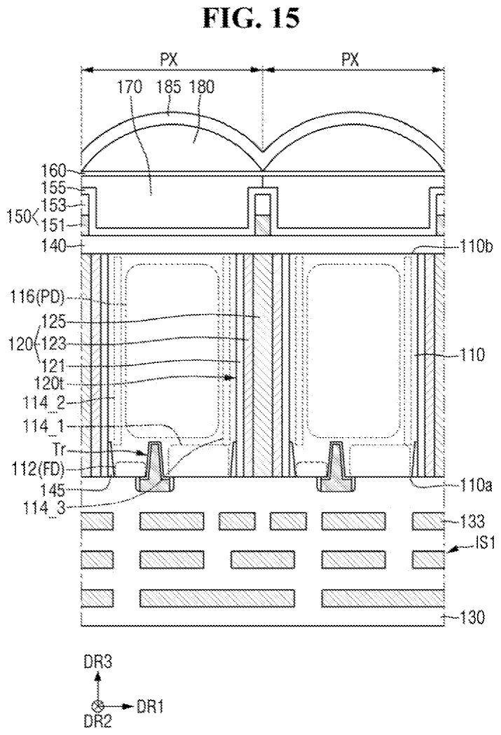

FIG. 15 is a cross-sectional view of an image sensor according to some embodiments of the present disclosure. For convenience, the image sensor of FIG. 15 will hereinafter be described, focusing mainly on the differences relative to the image sensor of FIG. 14.

Referring to FIG. 15, the image sensor may include well regions (114_1, 114_2, and 114_3), and the well regions (114_1, 114_2, and 114_3) may include first parts 114_1, second parts 114_2, and third parts 114_3. The first parts 114_1 may correspond to the well regions 114 of FIG. 14.

The second parts 114_2 and the third parts 114_3 may be disposed on sidewalls of the first pixel separation patterns 120. The second parts 114_2 and the third parts 114_3 may extend along the sidewalls of the first pixel separation patterns 120. The second parts 114_2 and the third parts 114_3 may be disposed between the first pixel separation patterns 120 and the photoelectric conversion regions 116. The second parts 114_2 may extend along first sidewalls of the first pixel separation patterns 120. The third parts 114_3 may extend along second sidewalls of the first pixel separation patterns 120. The photoelectric conversion regions 116 may be disposed between the first sidewalls and the second sidewalls of the first pixel separation patterns 120.

The second parts 114_2 may be spaced apart from the impurity regions 112. In some embodiments, the third parts 114_3 may extend along the second sidewalls of the first pixel separation patterns 120 to be connected to the first parts 114_1.

For example, as described above with FIGS. 5 through 7, each of the first pixel separation patterns 120 may further include at least one of a first barrier film 122 and a third conductive film 124.

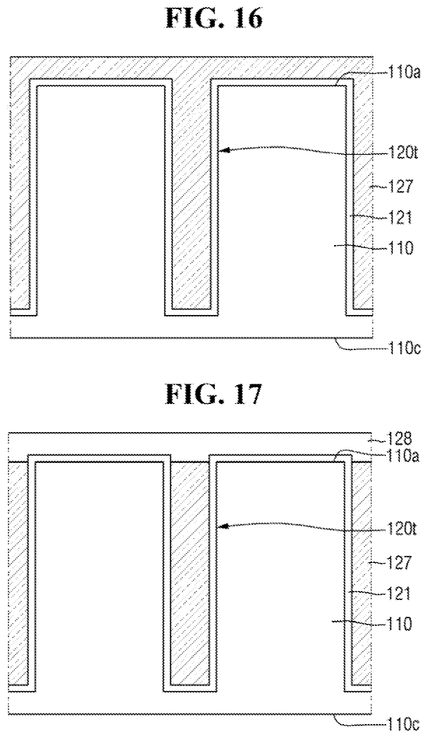

FIGS. 16 through 21 are cross-sectional views of stages in a method of fabricating an image sensor according to some embodiments of the present disclosure.

Referring to FIG. 16, the first substrate 110, which has first and third surfaces 110a and 110c that are opposite to each other, may be provided. The first pixel separation trenches 120t may be formed in the first substrate 110. The first pixel separation trenches 120t may be formed by etching the first substrate 110 in a direction oriented from the first surface 110a to the third surface 110c. The bottom surfaces of the first pixel separation trenches 120t may be formed within the first substrate 110.

Thereafter, the first insulating film 121 may be formed, e.g., conformally, on the bottom surface and the sidewalls of each of the first pixel separation trenches 120t and on the first surface 110a of the first substrate 110. The first insulating film 121 may extend along the bottom surface and the sidewalls of each of the first pixel separation trenches 120t. The first insulating film 121 may extend along the first surface 110a of the first substrate 110.

Thereafter, a first sacrificial film 127 may be formed on the first insulating film 121. The first sacrificial film 127 may fill the first pixel separation trenches 120t. The first sacrificial film 127 may cover the first surface 110a of the first substrate 110. The first sacrificial film 127 may include at least one of, e.g., silicon nitride and polysilicon.

Referring to FIG. 17, part of the first sacrificial film 127 may be etched. The first sacrificial film 127 may fill the first pixel separation trenches 120t, but may expose the first insulating film 121 on the first surface 110a of the first substrate 110, e.g., portions of the first sacrificial film 127 may be removed to expose the first insulating film 121 on the first surface 110a of the first substrate 110.

Thereafter, a second sacrificial film 128 may be formed on the first surface 110a of the first substrate 110. The second sacrificial film 128 may cover the first insulating film 121 and the first sacrificial film 127.

Alternatively, the second sacrificial film 128 may not be formed, but the transistors Tr and the first wiring structure IS1 of FIG. 3 may be formed on the first surface 110a of the first substrate 110. The first wiring structure IS1 may include the first wiring insulating film 130 and the plurality of first wires 133 in the first wiring insulating film 130.

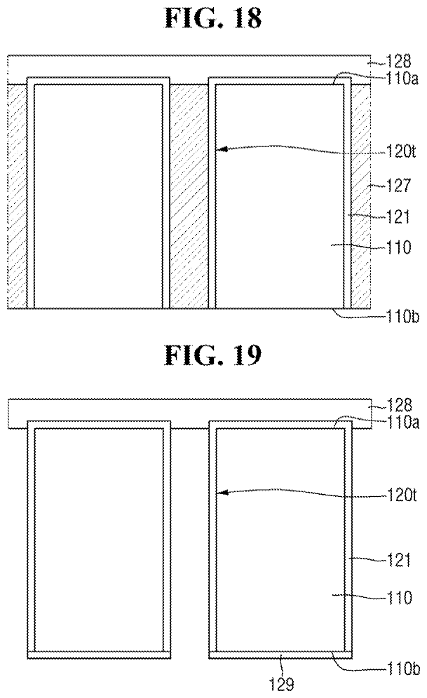

Referring to FIG. 18, part of the first substrate 110 may be etched. Part of the first substrate 110 may be etched from the third surface 110c of the first substrate 110, e.g., a thickness of the first substrate 110 may be reduced by removing a portion of the first substrate 110 from the third surface 110c of the first substrate 110 to define the second surface 100b. As a result, the first substrate 110 may have the first surface 110a and the second surface 110b, which are opposite to each other.

Referring to FIG. 19, a passivation film 129 may be formed on the second surface 110b of the first substrate 110. Thereafter, the first sacrificial film 127 may be removed. As a result, the first insulating film 121 may be exposed on the sidewalls of each of the first pixel separation trenches 120t.

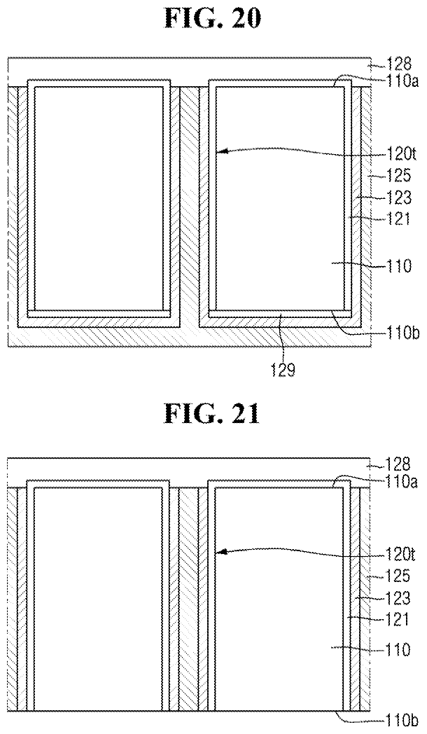

Referring to FIG. 20, the first conductive film 123 may be formed on the first insulating film 121 and the passivation film 129. The first conductive film 123 may extend along the first insulating film 121 and the passivation film 129. The second conductive film 125 may be formed on the first conductive film 123. The second conductive film 125 may fill the first pixel separation trenches 120t.

Referring to FIG. 21, the second conductive film 125, the first conductive film 123, the first insulating film 121, and the passivation film 129 may be removed from the second surface 110b, e.g., while portions of the second conductive film 125, the first conductive film 123, and the first insulating film 121 still fill the first pixel separation trenches 120t. Therefore, the second surface 110b of the first substrate 110 may be exposed, and the first pixel separation patterns 120 may be formed.

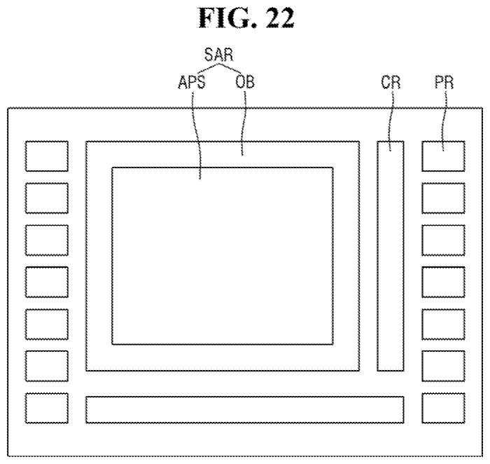

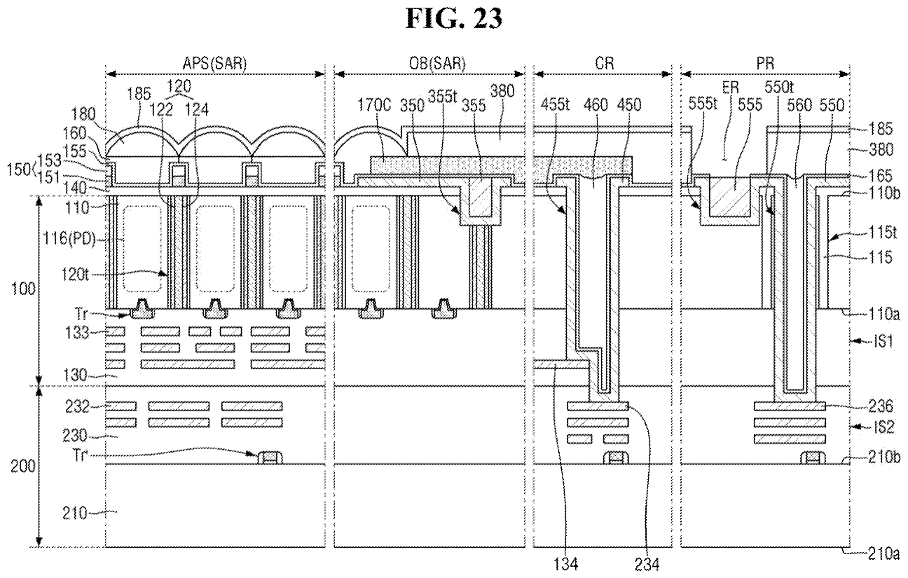

FIG. 22 is a layout view of an image sensor according to some embodiments of the present disclosure. FIG. 23 is a cross-sectional view of an image sensor according to some embodiments of the present disclosure. For convenience, the image sensor of FIGS. 22 and 23 will hereinafter be described, focusing mainly on the differences relative to the image sensor of FIGS. 1 through 15. FIG. 23 is a cross-sectional view of a sensor array region SAR of FIG. 22.

Referring to FIGS. 22 and 23, the image sensor may include the sensor array region SAR, a connecting region CR, and a pad region PR. The sensor array region SAR may include an area corresponding to the APS array 15 of FIG. 1. For example, a plurality of unit pixels (PX of FIG. 3), which are arranged two-dimensionally (e.g., in the form of a matrix), may be formed in the sensor array region SAR.

Referring to FIG. 22, the sensor array region SAR may include a light-receiving region APS and a light-blocking region OB. Active pixels, which receive light and generate active signals, may be arranged in the light-receiving region APS. Optical black pixels, which generate optical black signals due to light being blocked, may be arranged in the light-blocking region OB. For example, the light-blocking region OB may be formed around the light-receiving region APS. In some embodiments, dummy pixels may be formed in the light-receiving region APS near the light-blocking region OB.

For example, the connecting region CR may be formed around the sensor array region SAR. In another example, the connecting region CR may be formed on one side of the sensor array region SAR. Wires may be formed in the connecting region CR to transmit electrical signals to, or receive electrical signals from, the sensor array region SAR.

The pad region PR may be formed around the sensor array region SAR. For example, the pad region PR may be formed near edges of the image sensor. The pad region PR may be connected to external devices and may thus allow electrical signals to be transmitted between the image sensor and the external devices.

For example, as illustrated in FIG. 22, the connecting region CR may be interposed between the sensor array region SAR and the pad region PR. However, the layout of the sensor array region SAR, the connecting region CR, and the pad region PR may vary.

Referring to FIG. 23, the first substrate 110 and the first wiring structure IS1 may form a first substrate structure 100.

In some embodiments, the first wiring structure IS1 may include the first wires 133 in the sensor array region SAR and second wires 134 in the connecting region CR. The first wires 133 may be electrically connected to the unit pixels in the sensor array region SAR. For example, the first wires 133 may be connected to the transistors Tr. At least some of the second wires 134 may be electrically connected to at least some of the first wires 133. Accordingly, the second wires 134 may be electrically connected to the unit pixels in the sensor array region SAR.

The image sensor may include a second substrate 210 and a second wiring structure IS2.

The second substrate 210 may be a bulk silicon substrate or a SOI substrate. The second substrate 210 may be a silicon substrate or may include a material other than silicon, e.g., silicon germanium, indium antimonide, a lead tellurium compound, indium arsenic, indium phosphide, gallium arsenide, or gallium antimonide. Alternatively, the second substrate 210 may be a base substrate having an epitaxial layer formed thereon.

The second substrate 210 may include third and fourth surfaces 210a and 210b, which are opposite to each other. In some embodiments, the fourth surface 210b of the second substrate 210 may face the first surface 110a of the first substrate 110.

A plurality of electronic elements may be formed on the second substrate 210. For example, transistors Tr′ may be formed on the fourth surface 210b of the second substrate 210. The transistors Tr′ may be electrically connected to the sensor array region SAR and may thus transmit electrical signals to, or receive electrical signals from, the unit pixels in the sensor array region SAR. For example, the transistors Tr′ may include electronic elements that form the control register block 11, the timing generator 12, the ramp signal generator 13, the row driver 14, and the readout circuit 16 of FIG. 1.

The second wiring structure IS2 may be formed on the second substrate 210. In some embodiments, the second wiring structure IS2 may be formed on the fourth surface 210b of the second substrate 210. The second substrate 210 and the second wiring structure IS2 may form a second substrate structure 200.

The second wiring structure IS2 may be attached on the first wiring structure IS1. For example, as illustrated in FIG. 23, the top surface of the second wiring structure IS2 may be attached to the bottom surface of the first wiring structure IS1.

The second wiring structure IS2 may include one or more wires. For example, the second wiring structure IS2 may include a second wiring insulating film 230 and a plurality of wires in the second wiring insulating film 230. Any suitable number and layouts of layers of wiring of the second wiring structure IS2 may be used.

At least some of the wires of the second wiring structure IS2 may be connected to the transistors Tr′. In some embodiments, the second wiring structure IS2 may include third wires 232 in the sensor array region SAR, fourth wires 234 in the connecting region CR, and fifth wires 236 in the pad region PR. In some embodiments, the fourth wires 234 may be the uppermost wires in the connecting region CR, and the fifth wires 236 may be the uppermost wires in the pad region PR.

The image sensor may further include first connecting structures 350, second connecting structures 450, and third connecting structures 550.

The first connecting structure 350 may be formed in the light-blocking region OB. The first connecting structure 350 may be formed on the first planarization layer 140, in the light-blocking region OB. In some embodiments, the first connecting structure 350 may be in contact with the first pixel separation patterns 120. For example, first trenches 355t, which expose the first pixel separation patterns 120, may be formed in the first substrate 110 and the first planarization layer 140, in the light-blocking region OB. The first connecting structures 350 may be formed in the first trenches 355t to be in contact with first pixel separation patterns 120 in the light-blocking region OB. In some embodiments, the first connecting structures 350 may extend along the profile of the sides and the bottom surface of their respective first trenches 335t. The first connecting structures 350 may include at least one of, e.g., Ti, TiN, Ta, TaN, W, Al, Cu, and a combination thereof.

In some embodiments, the first connecting structures 350 may be electrically connected to the first pixel separation patterns 120 and may thus apply a ground voltage or a negative voltage to the first pixel separation patterns 120. As a result, electric charge generated by, e.g., ESD, can be released to the first connecting structures 350 through the first pixel separation patterns 120, and ESD defects may be effectively prevented.

In some embodiments, first pads 355, which fill the first trenches 355t, may be formed on the first connecting structures 350. The first pads 355 may include at least one of, e.g., W, Cu, Al, gold (Au), Ag, and an alloy thereof.

In some embodiments, the first passivation film 155 may cover the first connecting structures 350 and the first pads 355. For example, the first passivation film 155 may extend along the profile of the first connecting structures 350 and the first pads 355.

The second connecting structures 450 may be formed in the connecting region CR. The second connecting structures 450 may be formed on the first planarization layer 140, in the connecting region CR. The second connecting structures 450 may electrically connect the first substrate structure 100 and the second substrate structure 200. For example, second trenches 455t, which expose the second wires 134 and the fourth wires 234, may be formed in the first and second substrate structures 100 and 200, in the connecting region CR. The second connecting structures 450 may be formed in the second trenches 455t and may connect the second wires 134 and the fourth wires 234. In some embodiments, the second connecting structures 450 may extend along the profile of the sides and the bottom surface of their respective second trenches 455t.

The second connecting structures 450 may include at least one of, e.g., Ti, TiN, Ta, TaN, W, Al, Cu, and a combination thereof. In some embodiments, the second connecting structures 450 may be formed on the same level as the first connecting structures 350.

In some embodiments, the first passivation film 155 may cover the second connecting structures 450. For example, the first passivation film 155 may extend along the profile of the second connecting structures 450.

In some embodiments, a first filling insulating film 460 may be formed on each of the second connecting structures 450 to fill each of the second trenches 455t. The first filling insulating film 460 may include at least one of, e.g., silicon oxide, aluminum oxide, tantalum oxide, and a combination thereof.

The third connecting structures 550 may be formed in the pad region PR. The third connecting structures 550 may be formed on the first planarization layer 140, in the pad region PR. The third connecting structures 550 may electrically connect the second substrate structure 200 and external devices.

For example, third trenches 550t, which expose the fifth wires 236, may be formed in the first and second substrate structures 100 and 200, in the pad region PR. The third connecting structures 550 may be formed in the third trenches 550t and may be in contact with the fifth wires 236. Also, fourth trenches 555t may be formed in the first substrate 110, in the pad region PR. The third connecting structures 550 may also be formed in the fourth trenches 555t and may thus be exposed. In some embodiments, the third connecting structures 550 may extend along the profile of the sides and the bottom surface of each of the third trenches 550t and the sides and the bottom surface of each of the fourth trenches 555t.

The third connecting structures 550 may include at least one of, e.g., Ti, TiN, Ta, TaN, W, Al, Cu, and a combination thereof. In some embodiments, the third connecting structures 550 may be formed on the same level as the first connecting structures 350 and the second connecting structures 450.

In some embodiments, a second filling insulating film 560 may be formed on each of the third connecting structures 550 to fill each of the third trenches 550t. The second filling insulating film 560 may include at least one of, e.g., silicon oxide, aluminum oxide, tantalum oxide, and a combination thereof. In some embodiments, the second filling insulating film 560 may be formed on the same level as the first filling insulating film 460.

In some embodiments, second pads 555, which fill the fourth trenches 555t, may be formed on the third connecting structures 550. The second pads 555 may include at least one of, e.g., W, Cu, Al, Au, Ag, and an alloy thereof. In some embodiments, the second pads 555 may be formed on the same level as the first pads 355.

In some embodiments, the first passivation film 155 may cover the third connecting structures 550. For example, the first passivation film 155 may extend along the profile of the third connecting structures 550. In some embodiments, the first passivation film 155 may expose the second pads 555.

In some embodiments, light-blocking color filters 170C may be formed on the first connecting structures 350 and the second connecting structures 450. For example, the light-blocking color filters 170C may be formed to cover parts of the first passivation film 155 in the light-blocking region OB and the connecting region CR. The light-blocking color filters 170C may include, e.g., blue filters.

In some embodiments, a third passivation film 380 may be formed on the light-blocking color filters 170C. For example, the third passivation film 380 may be formed to cover parts of the first passivation film 155 in the light-blocking region OB, the connecting region CR, and the pad region PR. In some embodiments, a second passivation film 185 may extend along the surface of the third passivation film 380. The third passivation film 380 may include, e.g., a light-transmitting resin. In some embodiments, the third passivation film 380 may include the same material as the microlenses 180.

In some embodiments, the second and third passivation films 185 and 380 may expose the second pads 555. For example, exposure openings ER, which expose the second pads 555, may be formed in the second and third passivation films 185 and 380. Accordingly, the second pads 555 may be connected to external devices and may thus allow the image sensor and the external devices to transmit electrical signals to, or receive electrical signals from, one another. That is, the second pads 555 may be input/output pads of the image sensor.

In some embodiments, device isolation patterns 115 may be formed in the first substrate 110. For example, device isolation trenches 115t may be formed in the first substrate 110. The device isolation patterns 115 may be formed in the device isolation trenches 115t.

For example, as illustrated in FIG. 23, the device isolation patterns 115 may be formed near the second connecting structures 450 in the connecting region CR and the third connecting structures 550 in the pad region PR. In another example, the device isolation patterns 115 may also be formed near the first connecting structures 350 in the light-blocking region OB.

The device isolation patterns 115 may include at least one of, e.g., silicon oxide, silicon nitride, silicon oxynitride, aluminum oxide, hafnium oxide, and a combination thereof. In some embodiments, the device isolation patterns 115 may be formed on the same level as the first planarization layer 140.

By way of summation and review, embodiments provide an image sensor with an improved product reliability. That is, according to embodiments, a pixel separation pattern between adjacent pixels may include a double structure, i.e., two conductive layers, inside a trench, such that a first layer exhibits high reflectance (e.g., a layer formed of Al or Cu) and the second layer exhibits easy processing, i.e., high coverage during deposition (e.g., a layer formed of W or polysilicon), thereby providing both high reflectance and high coverage.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor, comprising:
a substrate including a first surface and a second surface, the first surface and the second surface being opposite to each other;
unit pixels in the substrate, the unit pixels including photoelectric conversion regions;
first pixel separation patterns in the substrate, the first pixel separation patterns defining the unit pixels, and each of the first pixel separation patterns including a first conductive film and a second conductive film; and
microlenses on the second surface of the substrate,
wherein the first conductive film extends along sidewalls of the second conductive film, the first conductive film separating the second conductive film from the substrate,
wherein the first conductive film has a greater reflectance than the second conductive film for a same predetermined wavelength range, and
wherein the second conductive film has a greater step coverage than the first conductive film.

2. The image sensor as claimed in claim 1, wherein:
the first conductive film has a reflectance of 0.7 or greater for a visible or infrared wavelength range, and
the second conductive film has a step coverage of 0.8 or greater.

3. The image sensor as claimed in claim 2, wherein the first conductive film includes at least one of aluminum, copper, and gold.

4. The image sensor as claimed in claim 1, wherein the second conductive film includes at least one of tungsten, polysilicon, and silicide.

5. The image sensor as claimed in claim 1, wherein each of the first pixel separation patterns further includes:
an insulating film extending along sidewalls of the first conductive film, the insulating film separating the first conductive film from the substrate, and
a barrier film between the insulating film and the first conductive film.

6. The image sensor as claimed in claim 1, wherein each of the first pixel separation patterns further includes a third conductive film between the first conductive film and the second conductive film.

7. The image sensor as claimed in claim 1, wherein the first pixel separation patterns extend from the first surface to the second surface of the substrate.

8. The image sensor as claimed in claim 1, wherein the first pixel separation patterns extend from the second surface of the substrate to only partially penetrate the substrate.

9. The image sensor as claimed in claim 1, wherein the second conductive film extends along a bottom surface of the first conductive film.

10. The image sensor as claimed in claim 1, further comprising second pixel separation patterns extending from the second surface of the substrate, the first pixel separation patterns extending from the first surface of the substrate toward the second pixel separation patterns.

11. The image sensor as claimed in claim 10, wherein:
each of the second pixel separation patterns includes a fourth conductive film and a fifth conductive film on the fourth conductive film, and
the fourth conductive film extends along sidewalls of the fifth conductive film.

12. The image sensor as claimed in claim 10, wherein the second pixel separation patterns include an insulating material.

13. An image sensor, comprising:
a substrate including a first surface and a second surface, the first surface and the second surface being opposite to each other;
unit pixels in the substrate, the unit pixels including photoelectric conversion regions;
first pixel separation patterns defining the unit pixels in the substrate, the first pixel separation patterns filling respective first pixel separation trenches;
well regions and floating diffusion regions in the substrate;
transistors on the first surface of the substrate;
a wiring structure including an inter-wiring insulating layer, which covers the transistors, and wires in the inter-wiring insulating layer; and
microlenses on the second surface of the substrate,
wherein each of the first pixel separation patterns includes a first insulating film extending along sidewalls of each of the first pixel separation trenches, a first conductive film on the first insulating film, and a second conductive film on the first conductive film and filling each of the first pixel separation trenches,
wherein the first conductive film has a greater reflectance than the second conductive film for a same predetermined wavelength range, and
wherein the second conductive film has a greater step coverage than the first conductive film.

14. The image sensor as claimed in claim 13, wherein at least some of the well regions extend along sidewalls of each of the first pixel separation patterns.

15. The image sensor as claimed in claim 13, further comprising device isolation patterns extending from the first surface of the substrate to penetrate part of the substrate, the first pixel separation patterns penetrating the device isolation patterns.

16. The image sensor as claimed in claim 13, wherein at least parts of the transistors are in the substrate.

17. An image sensor, comprising:
a substrate including a first surface and a second surface, the first surface and the second surface being opposite to each other;
first pixel separation patterns extending from the first surface to the second surface of the substrate and filling first pixel separation trenches;
unit pixels including photoelectric conversion regions in the substrate, the unit pixels being defined by the first pixel separation patterns; and
microlenses on the second surface of the substrate,
wherein each of the first pixel separation patterns includes a first insulating film on sidewalls of each of the first pixel separation trenches, a first conductive film on the first insulating film, and a second conductive film on the first conductive film and filling each of the first pixel separation trenches, and
wherein the first conductive film has a greater reflectance than the second conductive film for a same predetermined wavelength range.

18. The image sensor as claimed in claim 17, wherein each of the first pixel separation patterns further includes a third conductive film between the first conductive film and the second conductive film.

19. The image sensor as claimed in claim 17, wherein each of the first pixel separation patterns further includes a barrier film between the first insulating film and the first conductive film.

20. The image sensor as claimed in claim 17, wherein the second conductive film has a greater step coverage than the first conductive film.
